(19) United States
(12) Patent Application Publication
(10) Pub. No.: US 2016/0182015 A1
(43) Pub. Date: Jun. 23, 2016

(54) FRACTIONAL AND INTEGER RATIO POLYPHASE INTERPOLATION FILTER

(71) Applicants: Vinay Gupta, Noida (IN); Arvind Kaushik, Ghaziabad (IN); Akshat Mittal, Greater Noida (IN); Amrit P. Singh, Ludhiana, IN (US)

(72) Inventors: Vinay Gupta, Noida (IN); Arvind Kaushik, Ghaziabad (IN); Akshat Mittal, Greater Noida (IN); Amrit P. Singh, Ludhiana, IN (US)

(21) Appl. No.: 14/576,149

(22) Filed: Dec. 18, 2014

(51) Int. Cl. H03H 17/02

(52) U.S. Cl. CPC H03H 17/0273

(57) ABSTRACT

A fractional and integer ratio polyphase interpolation filter changes the sample rate of an input digital signal by a ratio defined by an interpolation rate, M, and a decimation rate, N. The clock rate required to evaluate the output signal is M/N.

### BACKGROUND OF THE INVENTION

The present invention relates generally to a filter for use in digital signal processing and, more particularly, to a fractional and integer ratio polyphase interpolation filter and method.

In digital signal processing systems, it is often necessary to convert a digitally encoded signal, such as an array of audio or video signal values, from one sample rate to another to make it usable in a given system. To perform this process digitally, an interpolation process, comprising zero stuffing and bandpass filtering above the output Nyquist rate, may be used to increase the sample rate by an integer factor, M, known as the interpolation factor. Conversely, a decimation process, comprising removing selected samples and bandpass filtering at the output Nyquist rate, may be used to reduce the sample rate by an integer factor, N, known as the decimation factor.

However, in practice, it is often necessary to change the sample rate of a signal by a non-integer, or fractional, factor. This may be achieved by first interpolating the input signal at an integer rate M, and then decimating the interpolated signal at an integer rate N, which can give the fractional rate change of M/N.

One common way of implementing a fractional rate change is to first use a polyphase interpolation filter 1 of the type shown in FIG. 1, and then to decimate the output interpolated signal.

Polyphase finite impulse response (FIR) interpolation filters calculate all the phases in parallel for each input sample using filter banks A, B, C, and so they are considered efficient. The three filter banks A, B, C, in the filter 1 interpolate the input signal by three in that they each provide a phase for a single input sample of the input digital signal.

The input digital signal is input into the filter 1 by being stored in plural taps 2, numbering T in total, of a digital delay line which may be provided by a circular buffer. The taps 2 are arranged in the three filter banks A, B, C, three per filter bank. Each tap 2 is provided with a respective multiplier 3 that multiplies the input signal value stored at that tap 2 by a filter coefficient hᵢ having an index i sequentially incremented in each filter bank by the interpolation rate M=3 (i.e., in filter bank A, the coefficients are h₀, hₘ and h₂ₘ). The multiplied input signals output by multipliers 3 in each bank A, B, C are then summed by adders 4 to provide an interpolated output signal for that phase of the input signal.

A commutater 5 operating at the interpolation rate M times the clock frequency is used to sequentially latch all of the output phases of the polyphase filter banks A, B, C in turn. After all the phases are read out, the input signal is clocked and the next input signal sample is latched into the first tap of the digital delay line. In this way, the polyphase interpolation filter avoids zero stuffing and filtering and efficiently calculates the interpolated phases in parallel.

However, as mentioned above, in order to implement fractional ratio, decimation logic provided after the interpolation filter, drops every ‘N’ sample (N is the decimation factor).

The complexity of the filter increases many fold if the interpolation and decimation rates are programmable. The filter coefficients on the different banks of the polyphase filter are different for different values of ‘M’.

It is in this context that the present invention is devised.

### BRIEF DESCRIPTION OF THE DRAWINGS

The invention, together with objects and advantages thereof, may best be understood by reference to the following description of preferred embodiments together with the accompanying drawings in which:

FIG. 1 shows a conventional polyphase interpolation filter;

FIG. 2 shows an example embodiment of a fractional and integer ratio polyphase interpolation filter in accordance with aspects of the invention;

FIGS. 3A and 3B are flow charts illustrating a method of operation of the fractional and integer ratio polyphase interpolation filter shown in FIG. 2 in accordance with aspects of the invention;

FIG. 4 illustrates, based on FIG. 2, the clocking of the input signal delay line and the evaluation of some fractionally interpolated output samples for M=5 and N=3; and

FIG. 5 illustrates, based on FIG. 2, the clocking of the input signal delay line and the evaluation of some fractionally interpolated output samples for M=3 and N=2.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

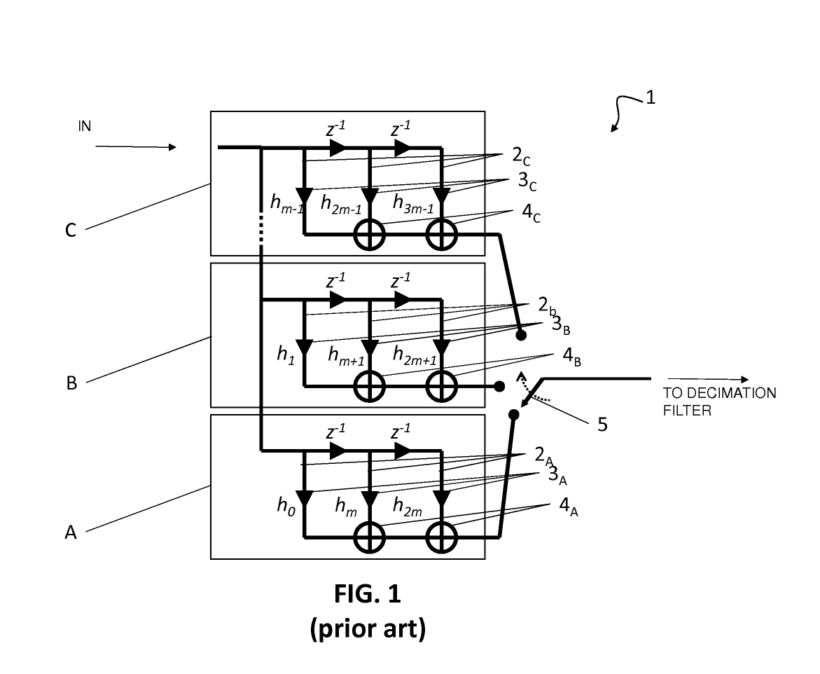

The present inventors have recognised that, in the conventional polyphase fractional interpolation filters of the type shown in FIG. 1, that the use of decimation logic after the interpolation to drops every ‘N’ sample adds significantly to power consumption and area. In the prior art polyphase fractional interpolation filter, the calculation of samples to be dropped is redundant and adds to power consumption. As a result, in the prior art polyphase fractional interpolation filters, the clock rate required to operate the filter on the input signal to provide the output signal samples is M times the input sample rate.

In addition, the present inventors have recognized that the provision of programmable polyphase filters arranged in banks, each having an array of multipliers and adders, as well as an additional decimation filter for fractional interpolation, means that the prior art programmable polyphase fractional interpolation filters occupy a significant area.

In one embodiment, the present invention provides a method of changing the sample rate of an input digital signal by a ratio defined by an interpolation rate, M, and a decimation rate, N. The method includes: storing, at plural taps of a digital delay line a delayed sequence of samples of the input signal; maintaining an accumulated sample index S; and calculating samples of an output digital signal by: (i) multiplying the sample of the input signal stored at each tap T by filter coefficients provided by a filter coefficient calculator based in part on S; (ii) summing the multiplied tap values to provide the filtered output signal sample; (iii) incrementing S by N and if the result is greater than the next integer multiple of M greater than S, then the digital delay line is clocked to move the samples of the input signal along the taps and introduce the next sample of the input signal; and (iV) returning to step (i).

In another embodiment, the present invention provides a filter that changes the sample rate of an input digital signal by a ratio defined by an interpolation rate, M, and a decimation rate, N. The filter includes: a digital delay line comprising plural taps arranged to, in use, store a delayed sequence of samples of the input signal; one multiplier for each tap; an adder coupled to the multipliers; and control logic arrange to maintain an accumulated sample index S and cause the filter to, in use, calculate samples of an output digital signal by: (i) the multipliers multiplying the sample of the input signal stored at each tap T by filter coefficients provided by a filter coefficient calculator based in part on S; (ii) the adder summing the multiplied tap values to provide the filtered output signal sample; (iii) the control logic incrementing S by N and if the result is greater than the next integer multiple of M greater than S, then the digital delay line is clocked to move the samples of the input signal along the taps and introduce the next sample of the input signal; and (iv) returning to step (i).

In yet another embodiment, the present invention provides a method of changing the sample rate of an input digital signal by a ratio defined by an interpolation rate, M, and a decimation rate, N. The method comprises: storing, at plural taps of a digital delay line a delayed sequence of samples of the input signal; calculating samples of an output digital signal using a polyphase filter; maintaining a signal index S incremented by N each calculation; and clocking the digital delay line to introduce the next input sample each time S is incremented beyond a multiple of M.

In accordance with these embodiments, the fractional (and integer) polyphase interpolation filter of the present invention reduces the power consumption and required clock rate compared to the prior art polyphase filters. In conventional polyphase filters where for a fractional interpolation by M/N, the filter is clocked at M times the input signal sample rate and the filter is operated every clock cycle and then N−1 calculated samples are dropped. This wastes power due to redundant sample calculation. In contrast, in accordance with the embodiments of the invention, the control logic sequences the input signal delay line and the output signal such that the filter architecture is operated/clocked only for exact fractional samples/samples necessary to produce the output signal samples. As a result, the filter is not operated to calculate any samples that are discarded and not used in the output signal. Where N−1 output samples are skipped each clock cycle. In addition, the filter is not required to be clocked at the rate of M times the rate of the input sample, but instead the filter of embodiments of the present invention is only required to be operated at a clock rate of M/N times the rate of the input sample. As a result, the power consumption of the fractional polyphase interpolation filter of the present invention consumes less power and operates at a lower clock rate to calculate the same output sample compared to the prior art polyphase filters.

Further, in accordance with these embodiments, the fractional (and integer) polyphase interpolation filter of the present invention occupies a reduced area as the multiplier and adder is shared for all branches/arms of the polyphase filter. Thus, in embodiments of the present invention, for a ‘T’ tap filter, instead of ‘T’ multipliers, only ‘T/M’ multipliers are used.

Thus the present invention provides a scalable FIR multi-rate interpolation polyphase filter architecture which allows programmable M/N values of filter operation with minimal area and power footprint by efficiently merging interpolation and decimation logic for fractional interpolation.

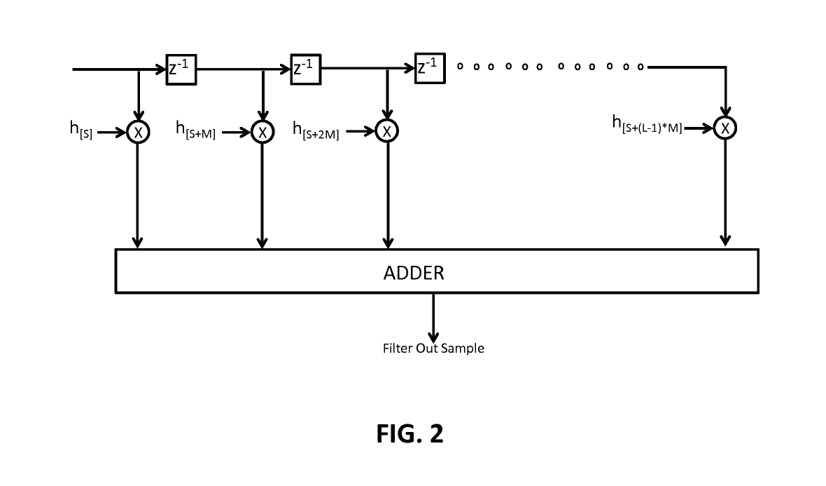

Referring now to FIG. 2, an example embodiment of a fractional and integer ratio polyphase interpolation filter 10 in accordance with aspects of the present invention is shown. In FIG. 2, S is a sample index from accumulator (starts from ‘0’), M is an interpolation factor, T is a total number of filter taps, K is a minimum interpolation supported, L is ceil [T/(K−1)], and coefficient value is zero if the index value is greater than (T−1).

The filter 10 is configured to change the sample rate of an input digital signal by a ratio defined by an interpolation rate, M, and a decimation rate, N.

The samples of the input digital signal are introduced to the filter as shown by the arrow in FIG. 2 at a digital delay line comprising plural taps 2. The taps 2 are arranged to, in use, store a delayed sequence of samples of the input signal. The digital delay line may be implemented by a circular buffer that, when clocked, causes the samples to move along the taps 2 by one place and introduces the new sample at the first tap, with the oldest sample being removed.

A multiplier 3 is provided for each tap 2 and is arranged to multiply the sample stored at the respective tap by an input filter coefficient provided to that multiplier by a filter coefficient provided by a filter coefficient calculator (not shown).

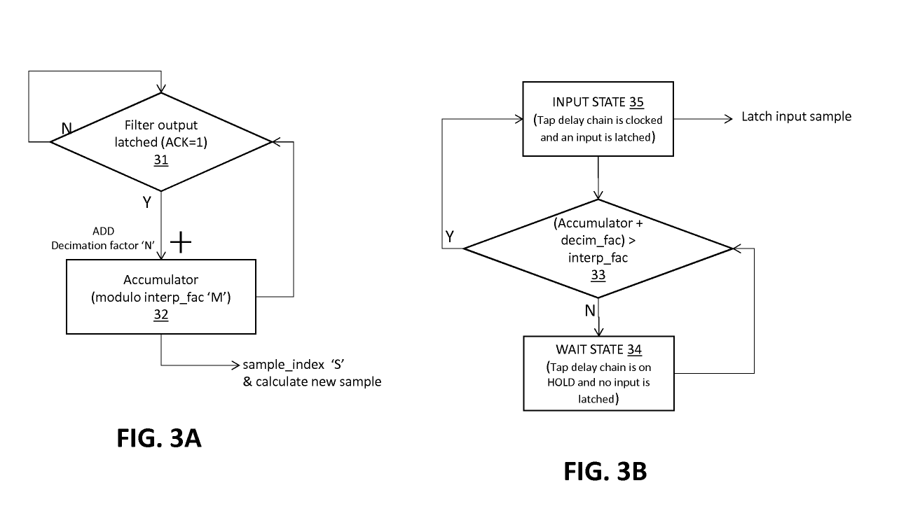

An adder 4 is provided, coupled to the multipliers and arranged to sum the multiplied tap values to provide the filtered output signal sample at the output indicated by the arrow in FIG. 3. As will be explained below, the signal output by the adder 4 is the fractionally interpolated input signal at the sample rate desired for the output signal. No further decimation process is necessary.

For this, control logic (not shown), which may be provided by a small state machine comprising only a few hundred logic gates, is provided, arranged to control the clocking and sequencing of the input and output samples and operation of the filter. The control logic maintains an accumulated sample index S that begins at zero. This sample index S is used to keep track of and sequence the input and output samples to ensure that the filter architecture is operated/clocked only for exact fractional samples necessary to produce the output signal samples.

A total number T of taps is provided and the filter 10 is designed to support a minimum interpolation rate K.

With reference now to the process flow diagrams of FIGS. 3A and 3B, a method of operation of the fractional and integer ratio polyphase interpolation filter of the embodiment shown in FIG. 2 will now be described. In FIGS. 3A and 3B, S is a sample index from the accumulator (starts from ‘0’); M=5, N=3; T=61, K=2, and L=ceil[61/2]=31.

First, the taps 2 of the filter 10 delay line are filled with the sequence of input samples and the filter 10 is operated to calculate the output sample for the current input samples stored in the taps 2 and the current value of the sample index S (initially S=0). To calculate the output sample, the multipliers 3 multiply the sample of the input signal stored at each tap 2 by filter coefficients h provided by the filter coefficient calculator.

The filter coefficients are based in part on S. Specifically, the multiplication coefficient component h for each tap in the delay line is h_{[S]} for the first tap and the filter coefficient component index is incremented each tap by the interpolation rate M, such that the filter coefficient is h_{[S+M]} for the next tap, h_{[S+2M]} for the next tap and so on in sequence up to h_{[S+L*M]}, where L=ceil [T/(K−1)], T is the number of taps in the delay line and K is the minimum interpolation rate supported in the filter design. The filter coefficients h for each filter coefficient index [S], [S+M], [S+2M] . . . [S+(L−1)*M] are calculated in the normal way for a polyphase filter by using the filter coefficient calculator, based on S and on the multiple of M for the given tap. However, the value of a given multiplication coefficient component h is zero if the coefficient index is greater than (T−1).

Once the output sample has been calculated for the current input samples stored in the taps 2 and the current value of the sample index S, the control logic performs, in parallel, the two control loops shown in FIGS. 3A and 3B, once per clock.

After filter 10 has been operated and the output sample for that clock cycle has been calculated, as can be seen in step 31 the control loop in FIG. 3A checks whether the filter output has been latched and is ready to receive the next output sample to be calculated by operation of the filter in the next clock cycle. If the output has not yet been latched, the process loops back on itself and waits until latching has occurred. Once latching has occurred, the process proceeds to step 32.

In step 32, the accumulator sample index S, which starts from a value S=0, is incremented by the decimation factor N. Preferably incrementing S by N is modulo M, with the remainder being carried over. At this point the process waits until the next sample is calculated in the next clock cycle and as shown, loops back to step 31 to wait for the next clock cycle to calculate the next output sample and wait until the output it again latched.

Similarly, after filter 10 has been operated and the output sample for that clock cycle has been calculated, the control loop in FIG. 3B tests at step 33 whether the value of the accumulator sample index S that has been incremented by the value of N has increased beyond (i.e., is now greater than) the next multiple of the interpolation factor M. If it has not, the process proceeds to step 34 in which the tap delay line is kept on hold in a wait state and no input is latched in the next clock cycle, and the process returns again to step 33 for the next clock cycle. If, on the other hand, the value of the accumulator sample index S that has been incremented by the value of N has increased beyond (i.e., is now greater than) the next multiple of the interpolation factor M, then the process continues to step 35 to introduce another input sample by clocking the tap delay line and latching another input sample. Thereafter, the process returns again to step 33 for the next clock cycle.

The incrementation of S by N each clock cycle in the control loop shown in FIG. 3A avoids the calculation by the filter of otherwise unnecessary phases of the interpolated signal that would have to be removed in a decimation operation to arrive at the fractional ratio output signal. That is, after every output sample calculation, N−1 of the phase calculations are skipped.

By the control process shown in FIG. 3B, the input sample cycling is sequenced to introduce new input signal samples when necessary, as the filter output calculation proceeds by skipping unnecessary phase calculations.

Thus, as a result of the operation of the filter 10 by the control logic implementing the control processes shown in FIGS. 3A and 3B, the filter calculates the output signal being a resampling of the input signal having a sample rate of M/N times the input sample rate.

The sequencing of the input and skipping the calculation of unnecessary output samples in this way avoids unnecessary calculations and saves significant power. This also allows the filter process to only be required to operate at a clock rate of M/N times the input signal rate.

In addition, the integration of the interpolation and decimation logic in the filter 10 and sharing of multipliers and adders in the polyphase filter arms/branches saves significant area.

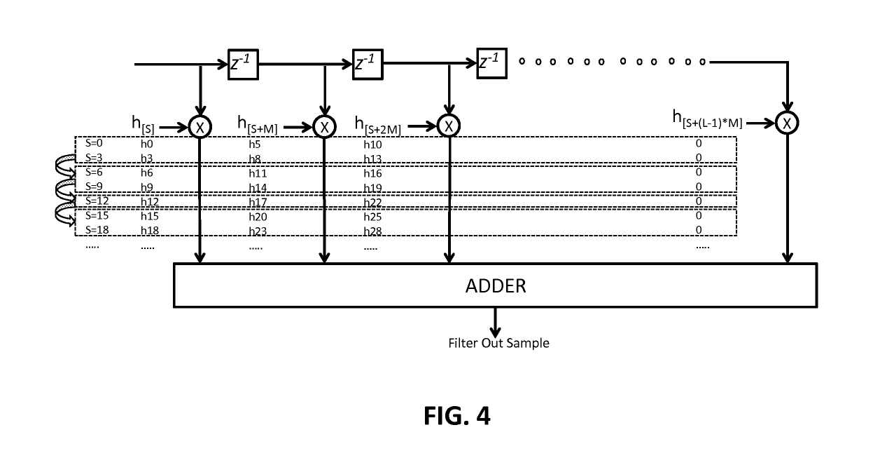

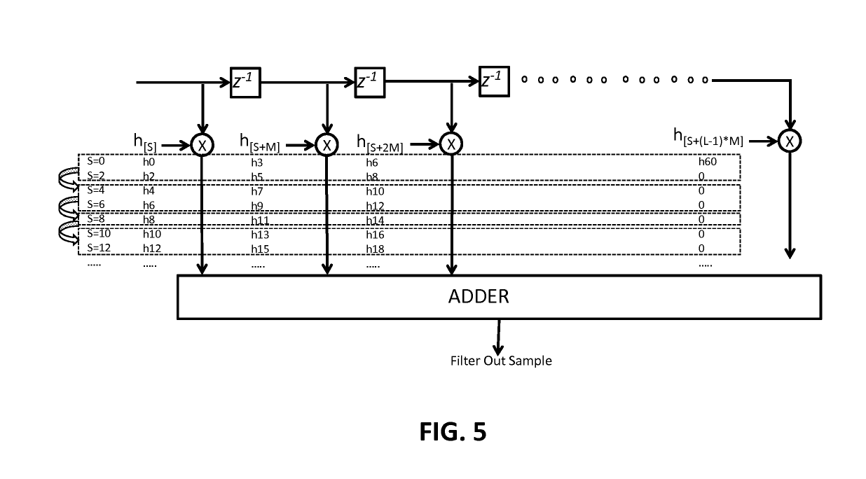

Example fractional interpolation calculations in accordance with the embodiments described in FIGS. 2 and 3 will now be described with reference to FIGS. 4 and 5. For example, as can be seen in FIG. 4, for a rate change of M/N=5/3, where the decimation factor is 3, due to the control process shown in FIG. 3A only the output sample for every third phase of the input sample is calculated by operation of the filter 10, as the value of S each clock cycle is incremented by 3 to give S=0, 3, 6, 9, 12 . . . . Note N−1 (in this case, 2) samples are skipped after each clock cycle such that these are not calculated unnecessarily.

Then, due to the control process shown in FIG. 3B, as the value of S+N becomes greater than the next multiple of M=5, the tap delay line is clocked and a new input sample is latched after the output sample calculation at S=3 (multiple of M=5); S=9 (multiple of M=10); S=12 (multiple of M=15), S=18 (multiple of M=20), etc. This is illustrated by the curved arrows. The separate dashed boxes encompass the set of output samples calculated from the same set of input samples stored in the delay line. As can be seen, due to the sequencing of the inputs and outputs by M/N=5/3, after the first set which includes two output samples, the number of output samples per set of input samples continues in the sequence 2,1,2,1,2,1,2, . . . .

The filter coefficients calculated by the filter coefficient calculator for generating the output sample are, in the example shown in FIG. 4 where M=5, for S=0, h0, h5, h10 . . . ; for S=3, h3, h8, h13 . . . ; for S=6, h6, h11, h16 . . . ; and so on. In the example shown in FIG. 4, T=61 so the filter coefficient for the last tap is zero as the coefficient index of [S+(L−1)*M]=150 for that tap is greater than T−1=60.

FIG. 5 shows another example of fractional interpolation calculations in accordance with the embodiments described in FIGS. 2 and 3A/3B for a rate change of M/N=3/2. In FIG. 5, S is the sample index from the accumulator (starts from ‘0’), M=3, N=2, T=61, K=3, and L=ceil[61/3]=21.

Due to the control process shown in FIG. 3A only the output sample for every second phase of the input sample is calculated by operation of the filter 10, as the value of S each clock cycle is incremented by 2 to give S=0, 2, 4, 6, 8, 10 . . . , where N−1 (in this case, 1) sample is skipped after each clock cycle such that these are not calculated unnecessarily.

Then, due to the control process shown in FIG. 3B, as the value of S+N becomes greater than the next multiple of M=3, the tap delay line is clocked and a new input sample is latched after the output sample calculation at S=2 (multiple of M=3); S=6 (multiple of M=6); S=8 (multiple of M=9), S=12 (multiple of M=12), etc. This is illustrated by the curved arrows. The separate dashed boxes encompass the set of output samples calculated from the same set of input samples stored in the delay line. As can be seen, due to the sequencing of the inputs and outputs by M/N=3/2, after the first set which includes two output samples, the number of output samples per set of input samples continues in the sequence 2,1,2,1,2,1,2, . . . .

The filter coefficients calculated by the filter coefficient calculator for generating the output sample are, in the example shown in FIG. 5 where M=3, for S=0, h0, h3, h6 . . . ; for S=2, h2, h5, h8 . . . ; for S=6, h4, h7, h10 . . . ; and so on. In the example shown in FIG. 5, T=61 so the filter coefficient for the last tap is h60 for S=0 as the coefficient index of [S+(L−1)*M]=60 for that tap is not greater than T−1=60.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A method of changing the sample rate of an input digital signal by a ratio defined by an interpolation rate, M, and a decimation rate, N, comprising:
storing, at plural taps of a digital delay line a delayed sequence of samples of the input signal;
maintaining an accumulated sample index S; and
calculating samples of an output digital signal by:
multiplying the sample of the input signal stored at each tap T by filter coefficients provided by a filter coefficient calculator based in part on S;
summing the multiplied tap values to provide the filtered output signal sample;
incrementing S by N and if the result is greater than the next integer multiple of M greater than S, then the digital delay line is clocked to move the samples of the input signal along the taps and introduce the next sample of the input signal; and
returning to the multiplying step.

2. The method of claim 1, wherein M is greater than N.

3. The method of claim 1, wherein the values on M and N are programmable.

4. The method of claim 1, wherein the starting value of S is zero.

5. The method of claim 1, wherein the clock rate required to produce the output signal is M/N times the input.

6. The method of claim 1, wherein the incrementing of S by N is calculated modulo M.

7. The method of claim 1, wherein the multiplication coefficient component h for each tap in the delay line is h_{[S]} for the first tap, h_{[S+M]} for the next tap, h_{[S+2M]} for the next tap and so on in sequence.

8. The method of claim 7, wherein the sequence for the multiplication coefficient component h continues until the tap for which h_{[S+(L-1)*M]} wherein L is evaluated by ceil(T/(K−1)), wherein T is the number of taps in the delay line and K is the minimum interpolation rate supported in the filter design.

9. The method of claim 8, wherein the value of a given multiplication coefficient component h is zero if the coefficient index is greater than (T−1).

10. A filter configured to change the sample rate of an input digital signal by a ratio defined by an interpolation rate, M, and a decimation rate, N, comprising:
a digital delay line having plural taps that store a delayed sequence of samples of the input signal;
a multiplier for each tap;
an adder coupled to the multipliers;
a filter coefficient calculator for providing filter coefficients; and
control logic that maintains an accumulated sample index S and causes the filter to calculate samples of an output digital signal by:
the multipliers multiplying the sample of the input signal stored at each tap T by filter coefficients provided the filter coefficient calculator based in part on S;
the adder summing the multiplied tap values to provide the filtered output signal sample;
the control logic incrementing S by N and if the result is greater than the next integer multiple of M greater than S, then the digital delay line is clocked to move the samples of the input signal along the taps and introduce the next sample of the input signal; and
returning to the multiplying step.

11. The filter of claim 10, wherein M is greater than n.

12. The filter of claim 10, wherein filter is configured such that the values on M and N are programmable.

13. The filter of claim 10, wherein the starting value of S is zero.

14. The filter of claim 10, wherein the clock rate required to produce the output signal is M/N times the input.

15. The filter of claim 10, wherein the control logic is configured such that the incrementation of S by N is calculated modulo m.

16. The filter of claim 10, further comprising a filter coefficient calculator that calculates the multiplication coefficient component h for each tap in the delay line as h_{[S]} for the first tap, h_{[S+M]} for the next tap, h_{[S+2M]} for the next tap, and so on in sequence.

17. The filter of claim 16, wherein the sequence for the multiplication coefficient component h continues until the tap for which h_{[S+(L-1)*M]} wherein L is evaluated by ceil (T/(K−1)) and wherein T is the number of taps in the delay line and K is the minimum interpolation rate supported in the filter design.

18. The filter of claim 17, wherein the value of a given multiplication coefficient component h is zero if the coefficient index is greater than (T−1).

19. A method of changing the sample rate of an input digital signal by a ratio defined by an interpolation rate, M, and a decimation rate, N, comprising:
storing, at plural taps of a digital delay line, a delayed sequence of samples of the input signal;
calculating samples of an output digital signal using a polyphase filter;
maintaining a signal index S incremented by N each calculation; and
clocking the digital delay line to introduce the next input sample each time S is incremented beyond a multiple of M.

20. The method of claim 19, wherein filter coefficients applied by the polyphase filter to multiply the input signal sample values at each tap are determined in part based on S.
